(19) United States
(12) Patent Application Publication
(10) Pub. No.: US 2025/0210846 A1
(43) Pub. Date: Jun. 26, 2025

(54) Electronic Component

(71) Applicant: Murata Manufacturing Co., Ltd., Nagaokakyo-shi Kyoto-fu (JP)

(72) Inventor: Ryoji TAKAZAWA, Nagaokakyo-shi (JP)

(21) Appl. No.: 19/079,367

(22) Filed: Mar. 13, 2025

Related U.S. Application Data
(63) Continuation of application No. PCT/JP2023/029058, filed on Aug. 9, 2023.

(30) Foreign Application Priority Data
Sep. 14, 2022 (JP) 2022-146197

(51) Int. Cl. H01P 7/06; H01P 7/10

(52) U.S. Cl. CPC H01P 7/06; H01P 7/10

(57) ABSTRACT

An electronic component includes: a multilayer body including a plurality of dielectric layers that are stacked; an external electrode disposed on at least one surface of external surfaces of the multilayer body; and internal electrodes disposed respectively in a plurality of layers of the multilayer body and connected to the external electrode. At least one cavity is formed in a dielectric layer between the internal electrodes, the at least one cavity being formed in a range of 0 μm to 200 μm in a direction from a connecting position where the external electrode is connected to the internal electrodes, the internal electrodes extending in the first direction.

### CROSS REFERENCE TO RELATED APPLICATION

This is a continuation of International Application No. PCT/JP2023/029058

filed on Aug. 9, 2023 which claims priority from Japanese Patent Application No. 2022-146197 filed on Sep. 14, 2022. The contents of these applications are incorporated herein by reference in their entireties.

### BACKGROUND OF THE DISCLOSURE

### Field of the Disclosure

The present disclosure relates to electronic components, and more specifically relates to a structure for preventing structural defects, formed in a dielectric, of an electronic component.

### Description of the Related Art

Japanese Patent Laid-Open No. 2007-235465 discloses a multilayer dielectric resonator having a structure in which a plurality of internal electrode layers are stacked together inside a dielectric body constituted of a plurality of dielectric layers.

### BRIEF SUMMARY OF DISCLOSURE

In the dielectric resonator disclosed in Japanese Patent Laid-Open No. 2007-235465, a plurality of internal electrode layers is connected to an external electrode of a metal material disposed on the front side surface of the dielectric body. In the dielectric body made of ceramic, resin, or the like, for example, when the plurality of dielectric layers are heated in a compression bonding step, stress is generated due to a difference in thermal shrinkage rate between the dielectric body and the external electrode, which may result in a structural defect in the vicinity of a portion connecting the internal electrode layers to the external electrode. Particularly in the structure in which the plurality of internal electrodes is connected to the external electrode, large stress is generated between the dielectric body and the electrodes, so that a crack is likely to be generated. If such a crack is generated, breakage of electrodes in the internal electrode layers or a solder burst may occur, which may lead to deterioration in the quality of products.

The present disclosure is made to solve such problems, and a possible benefit of the present disclosure is to prevent structural defects in an electronic component including a plurality of internal electrodes inside a dielectric body.

An electronic component according to the present disclosure includes: a multilayer body including a plurality of dielectric layers that are stacked; an external electrode disposed on at least one surface of external surfaces of the multilayer body; and internal electrodes disposed respectively in a plurality of layers of the multilayer body and connected to the external electrode. At least one cavity is formed in a dielectric layer between the internal electrodes, the at least one cavity being formed in a range of 0 μm to 200 μm in a first direction from a connecting position where the external electrode is connected to the internal electrodes, the internal electrodes extending in the first direction.

In the electronic component according to the present disclosure, a cavity/cavities is/are formed between a plurality of internal electrodes inside the multilayer body, the cavity being formed in the vicinity of (in a range of 0 μm to 200 μm from) the connecting position where the internal electrodes are connected to the external electrode. In such a structure, strain due to a difference in thermal shrinkage rate between the dielectric in the multilayer body and the external electrode is released by the cavity/cavities so that stress is alleviated. Thus, occurrence of cracks in the dielectric is suppressed. Accordingly structural defects in the electronic component can be prevented.

### BRIEF DESCRIPTION OF THE SEVERAL VIEWS OF THE DRAWINGS

FIG. 1 is a block diagram of a communication apparatus including a radio frequency front-end circuit to which a filtering device is applicable, the filtering device being an example of an electronic component according to an embodiment.

FIG. 2 is an external perspective view of the filtering device in FIG. 1.

FIG. 3 is a transparent perspective view illustrating an internal structure of the filtering device in FIG. 2.

FIG. 4 is a cross-sectional view of the filtering device in FIG. 2 as seen in an X-axis direction.

FIG. 5 is a diagram for illustrating a cross-sectional structure in the vicinity of an external electrode, in each of respective filtering devices of an embodiment and a comparative example.

FIG. 6 is a diagram illustrating a first example of a process of forming a cavity.

FIG. 7 is a diagram illustrating a second example of the process of forming a cavity.

FIG. 8 is a diagram for illustrating conditions for an experiment.

FIG. 9 is a diagram illustrating the experimental results in the case where cavities are formed in accordance with a process in FIG. 6.

FIG. 10 is a diagram illustrating the experimental results in the case where cavities are formed in accordance with a process in FIG. 7.

FIG. 11 is a cross-sectional view of a filtering device according to Modification 1, as seen in the X-axis direction.

FIG. 12 is a diagram for illustrating the experimental results including the filtering device according to Modification 1.

FIG. 13 is a cross-sectional view of a filtering device according to Modification 2, as seen in a Y-axis direction.

### DETAILED DESCRIPTION OF THE DISCLOSURE

Embodiments of the present disclosure are hereinafter described in detail with reference to the drawings. In the drawings, the same or corresponding parts are denoted by the same reference characters, and a description thereof is not herein repeated.

### Basic Configuration of Communication Apparatus

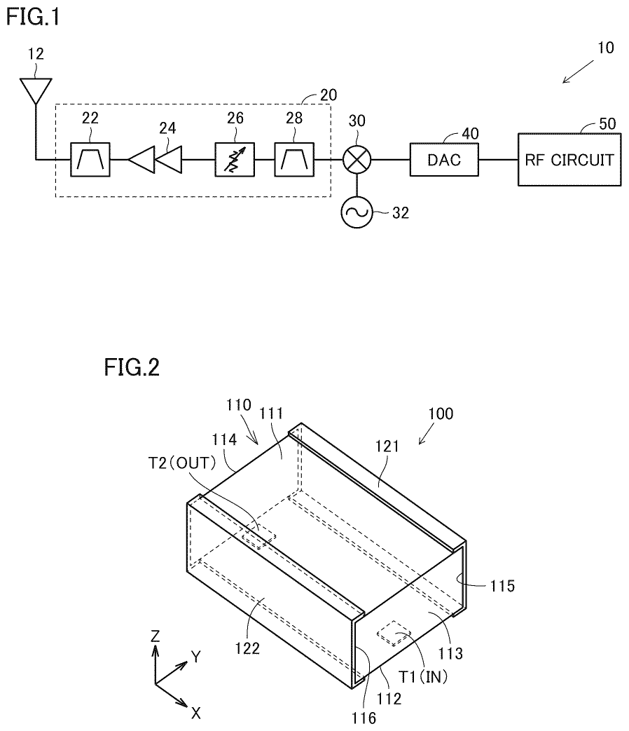

FIG. 1 is a block diagram of a communication apparatus 10 including a radio frequency front-end circuit 20 to which a filtering device is applicable, the filtering device being an example of an electronic component according to an embodiment. Examples of communication apparatus 10 may include, for example, mobile terminals, typically smartphones, and base stations for mobile telephones.

With reference to FIG. 1, communication apparatus 10 includes an antenna 12, a radio frequency front-end circuit 20, a mixer 30, a local oscillator 32, a D/A converter (DAC) 40, and an RF circuit 50. Radio frequency front-end circuit 20 includes bandpass filters 22 and 28, an amplifier 24, and an attenuator 26. In the following description referring to FIG. 1, radio frequency front-end circuit 20 includes a transmission circuit that transmits radio frequency signals from antenna 12, however, radio frequency front-end circuit 20 may also include a reception circuit that receives radio frequency signals through antenna 12.

Communication apparatus 10 up-converts a signal transmitted from RF circuit 50 into a radio frequency signal and outputs the radio frequency signal from antenna 12. A modulated digital signal output from RF circuit 50 is converted by D/A converter 40 into an analog signal. Mixer 30 mixes the analog signal generated by D/A converter 40 with an oscillation signal from local oscillator 32 to up-convert the resulting signal into a radio frequency signal. Bandpass filter 28 removes any unwanted wave generated by the up-conversion and thus extracts only the signal within a desired frequency band. Attenuator 26 adjusts the intensity of the signal. Amplifier 24 amplifies the signal having passed through attenuator 26 to a predetermined power level. Bandpass filter 22 removes any unwanted wave generated during the amplification and passes only signal components within a frequency band specified by the communication standards. The signal having passed through bandpass filter 22 is emitted from antenna 12 as a transmission signal.

The filtering device configured as disclosed herein may be used as bandpass filters 22, 28 of communication apparatus 10 described above.

### Configuration of Filtering Device

A configuration of a filtering device 100 according to the embodiment is hereinafter described in detail with reference to FIGS. 2 to 4. Filtering device 100 is a dielectric filter including a plurality of resonators, each of which defines and functions as a distributed parameter element.

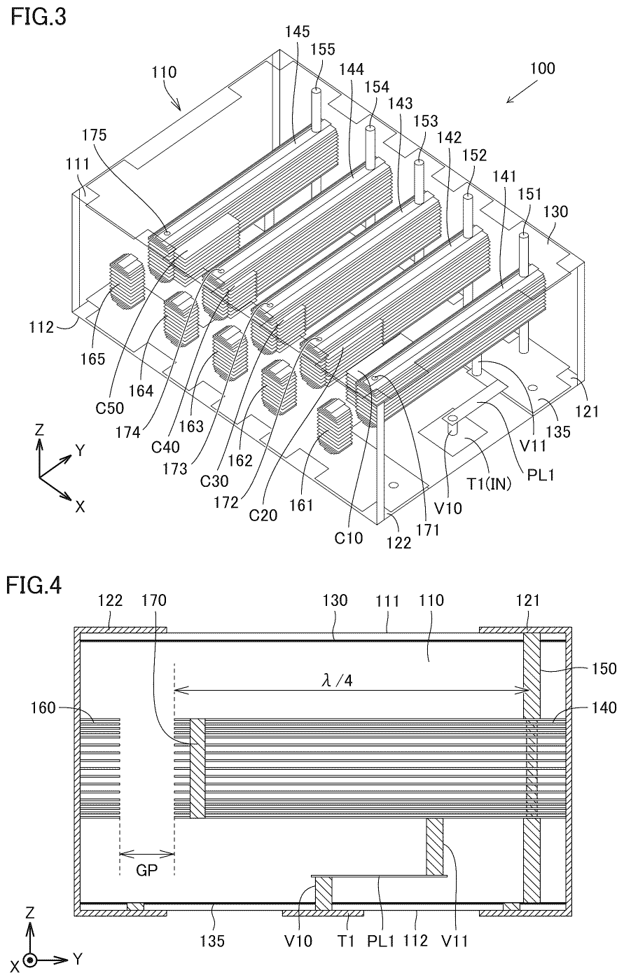

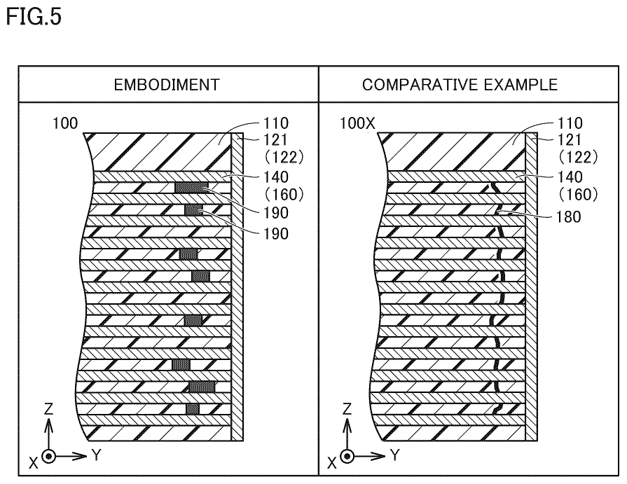

FIG. 2 is an external perspective view of filtering device 100. FIG. 2 shows only structural features of filtering device 100 that are visible from its outer surface side, and does not show its internal structural features. FIG. 3 is a transparent perspective view illustrating an internal structure of filtering device 100. FIG. 4 is a cross-sectional view of filtering device 100 as seen in an X-axis direction.

With reference to FIG. 2, filtering device 100 includes a cuboidal or substantially cuboidal multilayer body 110 including a plurality of dielectric layers stacked together in the stacking direction. Multilayer body 110 has an upper surface 111, a lower surface 112, a lateral surface 113, a lateral surface 114, a lateral surface 115, and a lateral surface 116. Lateral surface 113 is a lateral surface in the positive direction of the X axis, while lateral surface 114 is a lateral surface in the negative direction of the X axis. Lateral surfaces 115 and 116 are perpendicular to the Y-axis direction.

The dielectric layers of multilayer body 110 are each made of resin or ceramic, for example, low temperature co-fired ceramics (LTCC). In multilayer body 110, a plurality of flat conductors on respective dielectric layers and a plurality of vias between the dielectric layers provide the distributed parameter elements defining the resonators as well as capacitors and inductors to couple the distributed parameter elements.

In the description below, “Z-axis direction” refers to the stacking direction of multilayer body 110, “X-axis direction” refers to the direction along the long sides of multilayer body 110 and perpendicular to the Z-axis direction, and “Y-axis direction” refers to the direction along the short sides of multilayer body 110. In the description below, the upper side and the lower side may respectively refer to the positive direction of the Z axis and the negative direction of the Z axis in the drawings. It should be noted that “Y-axis direction” and “X-axis direction” in the present embodiment correspond to “first direction” and “second direction” respectively in the present disclosure.

As illustrated in FIG. 2, filtering device 100 includes shield conductors 121 and 122 that cover lateral surfaces 115 and 116, respectively, of multilayer body 110. Shield conductors 121 and 122 each have a substantially C shape when viewed in the X-axis direction of multilayer body 110. Thus, shield conductors 121 and 122 respectively cover a portion of upper surface 111 and a portion of lower surface 112 of multilayer body 110. Respective portions of shield conductors 121 and 122 on lower surface 112 of multilayer body 110 are connected, with connecting members such as solder bumps, to ground electrodes on a mounting substrate, which is not shown. Thus, shield conductors 121 and 122 also function as ground terminals.

Filtering device 100 includes an input terminal T1 and an output terminal T2 disposed on lower surface 112 of multilayer body 110. Input terminal T1 is disposed at a position on lower surface 112 relatively closer to lateral surface 113 in the positive direction of the X axis. Output terminal T2 is disposed at a position on lower surface 112 relatively closer to lateral surface 114 in the negative direction of the X axis. Input terminal T1 and output terminal T2 are connected, with connecting members such as solder bumps, to corresponding electrodes on the mounting substrate.

Next, the internal structure of filtering device 100 is described with reference to FIG. 3. Filtering device 100 includes, in addition to the structural features illustrated in FIG. 2, plate electrodes 130 and 135, a plurality of resonators 141 to 145, connecting conductors 151 to 155 and 171 to 175, and capacitor electrodes 161 to 165. In the following description, resonators 141 to 145, connecting conductors 151 to 155, and connecting conductors 171 to 175 may also be referred to collectively as “resonator 140,” “connecting conductor 150,” and “connecting conductor 170,” respectively.

Plate electrodes 130 and 135 are disposed facing each other at respective positions spaced apart in the stacking direction (Z-axis direction) in multilayer body 110. Plate electrode 130 is disposed on a dielectric layer close to upper surface 111, and is connected to shield conductors 121 and 122 at respective ends of multilayer body 110 along the X axis. As seen in a plan view in the stacking direction, plate electrode 130 has a shape that substantially covers the dielectric layers.

Plate electrode 135 is disposed on a dielectric layer close to lower surface 112. As seen in a plan view in the stacking direction, plate electrode 135 has a substantially H shape with cutouts formed in respective portions corresponding to input terminal T1 and output terminal T2. Plate electrode 135 is connected to shield conductors 121 and 122 at respective ends of multilayer body 110 along the X axis.

In multilayer body 110, resonators 141 to 145 are disposed between plate electrodes 130 and 135. Resonators 141 to 145 each extend in the Y-axis direction. Respective ends of resonators 141 to 145 in the positive direction of the Y axis (first ends) are connected to shield conductor 121. Respective ends of resonators 141 to 145 in the negative direction of the Y axis (second ends) are spaced away from shield conductor 122.

In multilayer body 110 of filtering device 100, resonators 141 to 145 are arranged side by side in the X-axis direction. Specifically, resonators 141, 142, 143, 144 and 145 are arranged in this order from the positive direction toward the negative direction of the X axis.

Resonators 141 to 145 each include a plurality of conductors arranged in the stacking direction. In a cross section parallel to a Z-X plane of each resonator, the plurality of conductors defines a substantially oval shape as a whole. In other words, the conductor in the uppermost layer and the conductor in the lowermost layer among the plurality of conductors have a dimension in the X-axis direction smaller than the dimension, in the X-axis direction, of conductors in layers located near the center. Generally, radio frequency current is known to mainly flow near the surface of a conductor because of the edge effect. Therefore, in the case where the whole of a plurality of conductors has a rectangular shape in a cross section, electric current is likely to concentrate on corner portions (i.e., ends of electrodes in the uppermost and lowermost layers). The substantially oval shape in a cross section of the plurality of conductors enables alleviation of such electric current concentration.

As illustrated in FIG. 4, resonator 140 is connected to plate electrodes 130 and 135 through connecting conductor 150, at respective positions near the first end. In filtering device 100, connecting conductor 150 extends from plate electrode 130 to plate electrode 135 through a plurality of conductors of a corresponding one of the resonators. The connecting conductor is electrically connected to a plurality of conductors defining a corresponding one of the resonators.

In each resonator 140, a plurality of conductors defining the resonator are

electrically interconnected through connecting conductor 170 at a position near the second end. Assuming that λ is the wavelength of a transmitted radio frequency signal of each resonator, the resonator is designed such that a distance between the second end of the resonator and connecting conductor 150 is approximately λ/4.

Resonator 140 functions as a distributed parameter TEM-mode resonator including a plurality of conductors as center conductors and plate electrodes 130 and 135 as outer conductors.

Resonator 141 is connected to input terminal T1 through vias V10 and V11 and a plate electrode PL1. Resonator 145 is connected to output terminal T2 through vias and a plate electrode, which is not seen in FIG. 3 because of being hidden behind the resonator. Resonators 141 to 145 are magnetically coupled to one another, and a radio frequency signal input to input terminal T1 is transmitted by resonators 141 to 145 and output from output terminal T2. At this time, filtering device 100 functions as a bandpass filter depending on the degree of coupling between the resonators.

On one side of resonator 140 closer to the second end, a capacitor electrode that protrudes between this resonator and another resonator adjacent thereto is provided. The capacitor electrode is structured such that some of the plurality of conductors defining the resonator protrude outward. The degree of capacitive coupling between the resonators is adjustable by the length of the capacitor electrode in the Y-axis direction, the distance from the capacitor electrode to the adjacent resonator, and/or the number of conductors defining the capacitor electrode.

In filtering device 100, a capacitor electrode C10 is disposed so as to protrude from resonator 141 toward resonator 142, and a capacitor electrode C20 is disposed so as to protrude from resonator 142 toward resonator 141, as illustrated in FIG. 3. Further, a capacitor electrode C30 is disposed so as to protrude from resonator 143 toward resonator 142, and a capacitor electrode C40 is disposed so as to protrude from resonator 144 toward resonator 143. Further, a capacitor electrode C50 is disposed so as to protrude from resonator 145 toward resonator 144.

Capacitor electrodes C10 to C50 are not indispensable features and, as long as a desired degree of inter-resonator coupling is achievable, some or all of capacitor electrodes C10 to C50 may not be provided. In addition to the features illustrated in FIG. 3, the filtering device may further include a capacitor electrode protruding from resonator 142 toward resonator 143, a capacitor electrode protruding from resonator 143 toward resonator 144, and a capacitor electrode protruding from resonator 144 toward resonator 145.

In addition, in filtering device 100, capacitor electrodes 160 are disposed so as to face the second ends of resonators 140, respectively. The shape of each capacitor electrode 160 in a cross section parallel to a Z-X plane is similar to that of resonator 140. Capacitor electrodes 160 are connected to shield conductor 122. Each resonator 140 and a corresponding one of capacitor electrodes 160 define a capacitor. The capacitance value of the capacitor defined by resonator 140 and capacitor electrode 160 is adjustable by adjusting a gap GP (distance in the Y-axis direction) between the resonator and the capacitor electrode illustrated in FIG. 4.

In the case of a structure in which dielectric layers of ceramic or the like and metal electrodes are stacked together, like the filtering device described above, a multilayer body is formed by heating the plurality of dielectric layers and by compression-bonding the dielectric layers and the electrodes to each other. The heating and cooling in such a compression-bonding step cause stress to be generated between the dielectric and the electrode due to a difference in thermal shrinkage rate between the dielectric and the electrode, which may result in a structural defect such as crack. If such a structural defect is generated, breakage of electrodes or burst of solder for connecting with an external device may occur, which may lead to deterioration in the quality of products.

In a structure in which a plurality of conductors (internal electrodes) defining a resonator or a capacitor electrode are connected to shield electrodes (external electrodes) disposed on respective lateral surfaces of a multilayer body, like the filtering device of the embodiment, the ratio of the metal to the dielectric is higher particularly in the vicinity of a portion where the external electrodes and the internal electrodes are connected to each other. r. Accordingly, the stress generated between the dielectric and the electrode is larger, so that a crack is more likely to be generated.

In view of this, for the filtering device of the present embodiment, a structure is adopted in which a cavity is formed in advance in the dielectric in the vicinity of the portion where the external electrode and the internal electrodes are connected to each other, and strain generated due to a difference in thermal shrinkage rate is released by the cavity, to thereby reduce the stress generated at the interface between the dielectric and the electrode. In this way, occurrence of a structural defect such as crack is suppressed, to prevent deterioration in quality of products.

FIG. 5 is a diagram for illustrating a cross-sectional structure in the vicinity of

an external electrode, in each of respective filtering devices according to an embodiment and a comparative example. In FIG. 5, a partial cross-sectional view of filtering device 100 according to the embodiment is illustrated on the left side, and a partial cross-sectional view of a filtering device 100X according to the comparative example is illustrated on the right side.

In filtering device 100X of the comparative example, the dielectric of multilayer body 110 fills the spaces between a plurality of conductors (i.e., internal electrodes) defining resonator 140 or capacitor electrode 160, without leaving gaps.

In contrast, in filtering device 100 of the embodiment, a cavity 190 is formed in a part of the dielectric between the internal electrodes.

Regarding such a structure, when multilayer body 110 is formed by thermal compression bonding of a plurality of stacked dielectric layers (ceramic layers) in a manufacturing process, a difference in thermal shrinkage rate between the dielectric layers and a metal portion defining the electrode may cause stress between the dielectric layers and the metal portion during heating and cooling, as descried above. In filtering device 100X of the comparative example, strain is caused by the generated stress, which may result in a structural defect like a crack 180 in the dielectric between internal electrodes. Generation of the crack may cause breakage of the internal electrode itself or burst of solder used for soldering the filtering device, which may lead to deterioration in the filtering property or deterioration in the quality such as joint failure.

Regarding filtering device 100 of the embodiment, in the dielectric between the internal electrodes, cavity 190 is formed in the vicinity of the portion connecting the external electrode and the internal electrodes. Therefore, stress generated in the manufacturing process is alleviated in cavity 190, so that occurrence of cracks is suppressed.

### Process of Forming Cavity

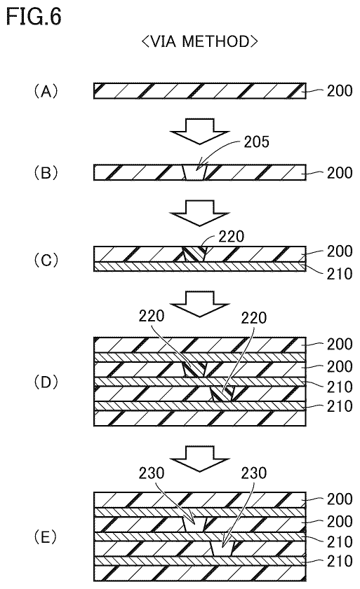

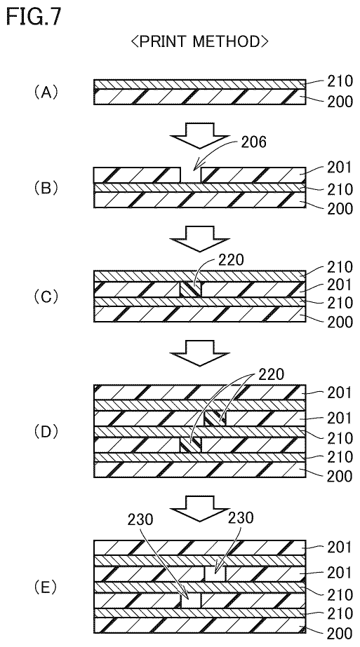

Next, with reference to FIGS. 6 and 7, a process of forming a cavity between internal electrodes is described.

### FIRST EXAMPLE

### Via Method

FIG. 6 is a diagram illustrating a first example of the process of forming a cavity. The process of the first example is generally a method according to which a via is formed in a ceramic green sheet with a laser or a drill or the like, resultant green sheets are stacked together, and the stack is fired. This process is herein referred to as “via method.”

With reference to FIG. 6, according to the via method, initially a ceramic green sheet 200 is prepared in Step (A). Then, in Step (B), an opening (via) 205 is formed at a desired position in target green sheet 200, using a laser with infrared or ultraviolet radiation, or using a drill or the like. After this, in Step (C), via 205 in green sheet 200 is filled with a resin paste 220, and a copper paste 210 is printed on one surface of green sheet 200. As resin paste 220, a material that is to be vaporized to disappear by firing in later Step (E) is used. As resin paste 220, a paste that is a mixture of resin such as acrylic resin and carbon is used, for example. For a layer in which via 205 is not formed, copper paste 210 is printed on green sheet 200 prepared in Step (A).

Then, in Step (D), green sheets 200 each having copper paste 210 printed thereon are stacked together to form a general shape of multilayer body 110. After this, in Step (E), the stack formed in Step (D) is fired to form multilayer body 110. At this time, heating during the firing causes resin paste 220 to be vaporized and disappear, leaving a cavity 230.

### SECOND EXAMPLE

### Print Method

FIG. 7 is a diagram illustrating a second example of the process of forming a cavity. The process of the second example is generally a method according to which a copper paste and a ceramic paste are printed alternately on a ceramic green sheet and the resultant stack is fired. This process is herein referred to as “print method.”

With reference to FIG. 7, according to the print method, a copper paste 210 is printed on a ceramic green sheet 200 in Step (A). Next, in Step (B), on printed copper paste 210, a ceramic paste 201 is printed. In Step (B), ceramic paste 201 is not printed in a region 206 that is to finally form a cavity. For a layer in which a cavity is not formed, ceramic paste 201 is printed on the entire surface of copper paste 210. Then, in Step (C), region 206 where ceramic paste 201 is not printed is filled with a resin paste 220 by printing, and thereafter copper paste 210 is printed on ceramic paste 201. A series of these steps is repeated to thereby form a general shape of multilayer body 110 (Step (D)).

Then, the stack formed in Step (D) is fired to form multilayer body 110. At this time, heating during the firing causes resin paste 220 to be vaporized and disappear, leaving a cavity 230.

### Results of Experiment

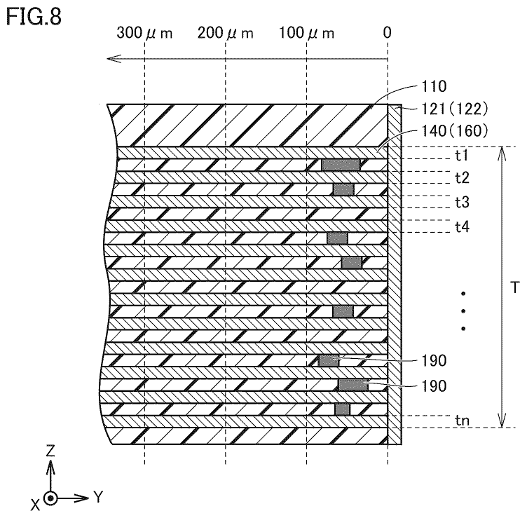

With reference to FIGS. 8 to 10, a description is given of the experimental

results in order to verify effects of the structure according to the present disclosure. In the experiment, chip samples of the multilayer body are produced by changing the position where the cavity is formed and by changing the number of dielectric layers in which respective cavities are formed, and the generated clacks in the dielectric layers are observed.

FIG. 8 is a diagram for illustrating experimental conditions described above. As the experimental conditions, (a) the number of conductor layers, (b) the distance (the cavity formation position where a cavity is formed) from shield conductor 121, 122 (external electrode) to a cavity, in the direction in which conductors (internal electrodes) defining resonator 140 and capacitor electrode 160 extend, and (c) the ratio of the number of layers in which respective cavities are formed to the total number of dielectric layers between the internal electrodes (the ratio of the number of cavity layers) were set. The crack occurrence rate was examined for each of these conditions that were changed. The crack occurrence rate is expressed as a ratio of the number of layers with cracks to the total number of dielectric layers between the internal electrodes.

The number of conductor layers is the total number of conductors defining resonator 140 and capacitor electrode 160. As the number of conductor layers, two layers (i.e., in the case of only the uppermost and lowermost conductors), 11 layers, 21 layers, and 51 layers were specified. As shown in FIG. 8, the thickness of multilayer body 110 from the uppermost conductor to the lowermost conductor is denoted by T, respective thicknesses of the conductors are denoted by t1 to tn, and the electrode ratio is defined as (t1+t2+ . . . +tn)/T. The electrode ratio in the case of the two layers is about 2 to 4%, the electrode ratio in the case of the 11 layers is about 11 to 13%, the electrode ratio in the case of the 21 layers is about 20 to 24%, and the electrode ratio in the case of the 51 layers is about 47 to 53%. Since respective positions of the uppermost and lowermost conductors are fixed, generally as the electrode ratio is higher, i.e., as the number of conductor layers is larger, the interfaces between the conductors and the dielectric layers increase, so that the area of portions where cracks may be generated increases.

The cavity formation position was set to 0 μm to 100 μm, 100 μm to 200 μm, and 200 μm to 300 μm, from the external electrode. The dimension of one cavity 190 in the width direction was set to 3 μm to 100 μm.

The crack occurrence rate was calculated, for the chip samples of filtering device 100 prepared under each of the conditions described above, by observing cross sections of N=100 samples for each condition, and identifying the number of samples with cracks. The crack occurrence rate was determined using cracks that were generated in the dielectric between the uppermost conductor and the lowermost conductor of the internal electrodes and located in a range of 0 μm to 300 μm from the external electrode.

### FIRST EXAMPLE

### Via Method

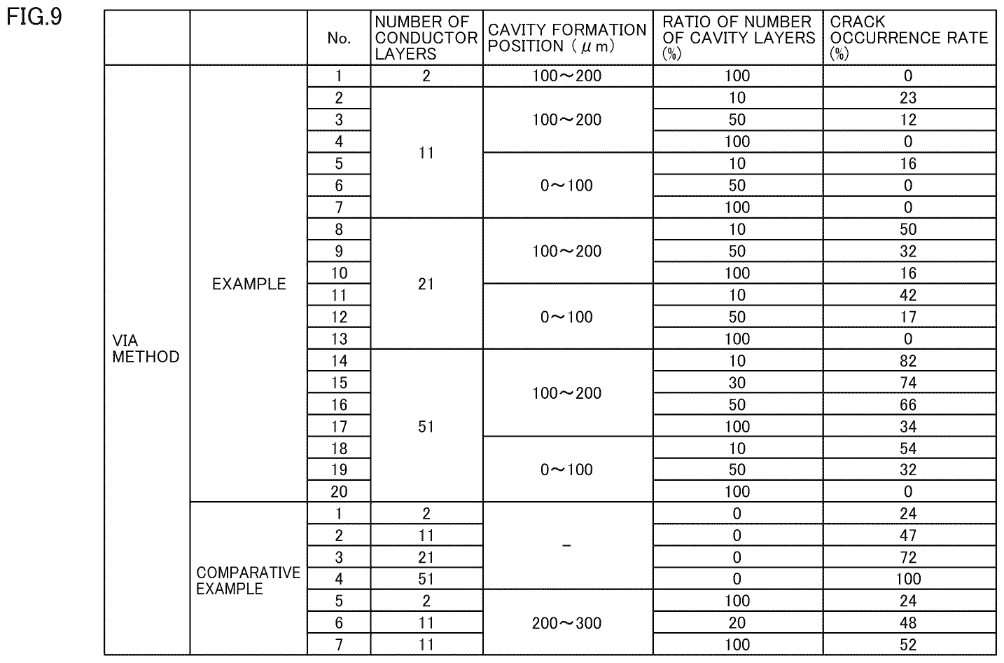

FIG. 9 illustrates the experimental results with samples prepared by the via method of the first example. FIG. 9 also illustrates, as comparative examples, samples in which no cavity was formed in each of the number of conductors, i.e., the ratio of the number of cavity layers was 0% (Comparative Examples 1 to 4), and samples in which the cavity formation position was 200 μm to 300 μm (Comparative Examples 5 to 7) that were observed.

Initially, regarding Comparative Examples, in the case where no cavity was formed (Comparative Examples 1 to 4), the crack occurrence rate was higher as the number of conductor layers is larger and, in the case where the conductor layers were 51 layers, cracks occurred with a probability of 100%. In addition, also in the case where the conductor layers were two layers including the uppermost layer and the lowermost layer, cracks occurred in about a quarter of the samples.

In the case of Comparative Examples 5 to 7 in which the cavity formation position was set to 200 μm to 300 μm, even when the ratio of the number of cavity layers was 100%, i.e., cavities were formed in all of the dielectric layers, cracks occurred with a probability of 24% to 52% in the dielectric located closer to the external electrode than to the cavity.

Regarding Examples, the tendency of the crack occurrence rate is the same as the Comparative Examples, and the crack occurrence rate increases with the increase of the number of conductor layers. However, it is seen, from a comparison between Examples and Comparative Examples with the same number of conductor layers, that the crack occurrence rate of all of these Examples is lower than that of these Comparative Examples. For example, in the case where the number of conductor layers is 11 (Examples 2 to 7), the crack occurrence rate is 0% to 23%, which is lower than the crack occurrence rate of 47% to 52% of Comparative Examples 2, 6, and 7.

In addition, regarding Examples with the same number of conductor layers, the crack occurrence rate is lower as the cavity formation position is closer to the external electrode. Specifically, the crack occurrence rate in the case where the cavity is formed in a range of 0 μm to 100 μm is lower than that in the case where the cavity is formed in a range of 100 μm to 200 μm. Further, regarding Examples with the same number of conductor layers and the same cavity formation position, the crack occurrence rate is lower as the ratio of the number of cavity layers is higher, i.e., the number of layers with cavities is larger.

It is seen, from the above experimental results, that the crack occurrence rate is decreased by setting the cavity formation position to a range of 0 μm to 200 μm from the external electrode, and the effect of reducing cracks is enhanced by setting the cavity formation position closer to the external electrode In addition, it is seen that the crack occurrence rate is lower as the ratio of the number of cavity layers is higher, i.e., as the number of dielectric layers with cavities is larger.

### SECOND EXAMPLE

### Print Method

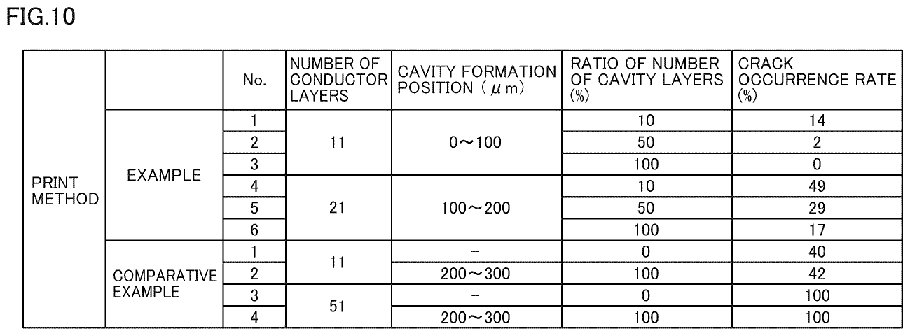

FIG. 10 illustrates the results of an experiment with samples prepared by the print method of the second example. In the case of the print method, substantially the same tendency as the via method is exhibited, and the crack occurrence rate is decreased by forming cavities in a range of 0 μm to 200 μm from the external electrode. In addition, the crack occurrence rate is lower as the number of dielectric layers in which cavities are formed is larger.

Thus, regardless of the method of forming cavities, the crack occurrence rate can be decreased by forming cavities in a range of 0 μm to 200 μm from the external electrode and/or by forming cavities in a larger number of dielectric layers.

In the above description, an electronic component which is a filtering device of the dielectric resonator type is illustrated by way of example, however, the features of the present disclosure are also applicable to other electronic components having a structure in which a plurality of electrode layers stacked in a dielectric body are connected to an external electrode. The other electronic components may be a capacitor, an inductor, or the like, for example.

### MODIFICATIONS

Modifications according to the present embodiment are hereinafter described.

### Modification 1

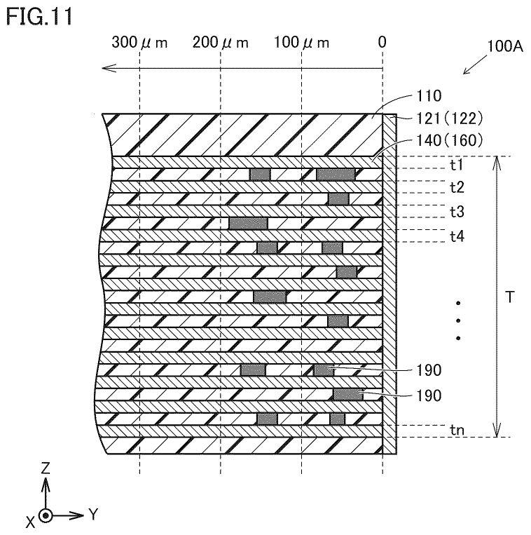

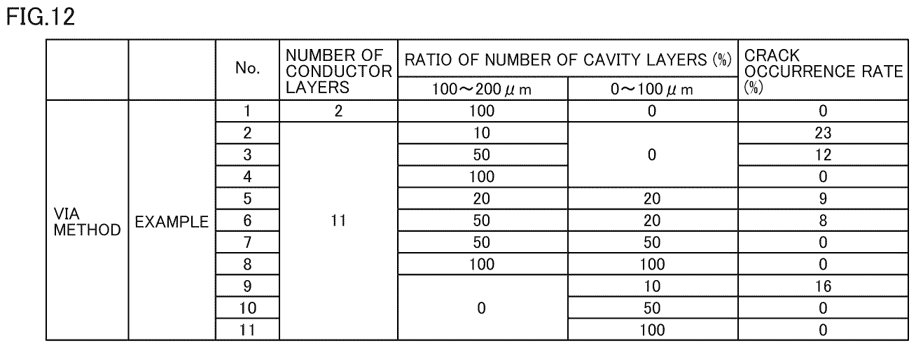

FIG. 11 is a cross-sectional view of a filtering device 100A according to Modification 1, as seen in the X-axis direction. In filtering device 100A, cavities 190 are formed not only at respective positions in a range of 0 μm to 100 μm from the external electrode but also at respective positions in a range of 100 μm to 200 μm from the external electrode. Regarding some of the dielectric layers, cavities 190 are formed at both of a position in a range of 0 μm to 100 μm and a position in a range of 100 μm to 200 μm from the external electrode, in the same dielectric layer (corresponding to “first cavity” and “second cavity” of the present disclosure). In such a case where cavities 190 are formed respectively in two regions, occurrence of cracks can also be suppressed since stress generated in the manufacturing process is alleviated in these cavities 190.

FIG. 12 is a diagram for illustrating the experimental results including filtering device 100A according to Modification 1. FIG. 12 shows the crack occurrence rate in the case where cavities 190 are formed at respective positions in both of a range of 0 μm to 100 μm and a range of 100 μm to 200 μm from the external electrode (Examples 5 to 8 in FIG. 12), in addition to the crack occurrence rate in the case where cavities 190 are formed only at respective positions in a range of 100 μm to 200 μm from the external electrode (Examples 1 to 4 in FIG. 12) and the case where cavities 190 are formed only at respective positions in a range of 0 μm to 100 μm from the external electrode (Examples 9 to 11 in FIG. 12).

FIG. 12 illustrates the results of the case where the number of conductor layers is two and the case where the number of conductor layers is 11, in the filtering device manufactured by the via method. Examples 1 to 4 in FIG. 12 correspond respectively to Examples 1 to 4 in FIG. 9, and Examples 9 to 11 in FIG. 12 correspond respectively to Examples 5 to 7 in FIG. 9.

Example 5 in Modification 1 is an example in which both the ratio of the number of cavity layers where the cavity formation position is 0 μm to 100 μm, and the ratio of the number of cavity layers where the cavity formation position is 100 μm to 200 μm are 20%. Example 6 in Modification 1 is an example in which the ratio of the number of cavity layers where the cavity formation position is 0 μm to 100 μm is 20%, and the ratio of the number of cavity layers where the cavity formation position is 100 μm to 200 μm is 50%.

Example 7 in Modification 1 is an example in which both the ratio of the number of cavity layers where the cavity formation position is 0 μm to 100 μm, and the ratio of the number of cavity layers where the cavity formation position is 100 μm to 200 μm are 50%. Example 8 in Modification 1 is an example in which both the ratio of the number of cavity layers where the cavity formation position is 0 μm to 100 μm and the ratio of the number of cavity layers where the cavity formation position is 100 μm to 200 μm are 100%.

As illustrated in FIG. 12, it is seen that the crack occurrence rate tends to be further decreased in the case where cavity formation positions are located in both the range of 0 μm to 100 μm and the range of 100 μm to 200 μm, as compared with the case where cavities 190 are formed in only one of the regions.

### Modification 2

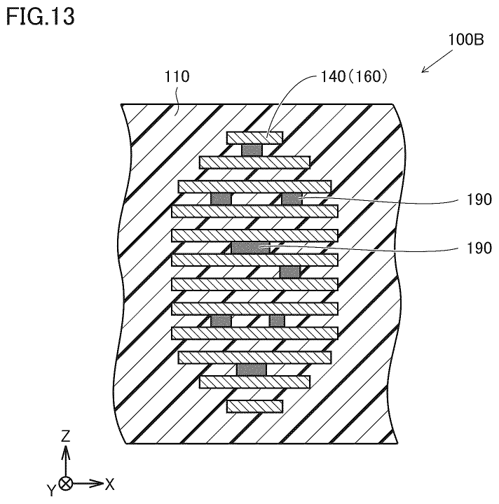

FIG. 13 is a cross-sectional view of a filtering device 100B according to Modification 2, as seen in the Y-axis direction. As illustrated in FIG. 13, in filtering device 100B, two cavities 190 (corresponding to “third cavity” and “fourth cavity” of the present disclosure) are disposed at respective positions offset from each other in the X-axis direction, in each of some of dielectric layers between conductors forming resonator 140 and capacitor electrode 160. Respective positions, in the Y-axis direction, of these two cavities 190 formed in the same dielectric layer may be identical to or different from each other.

In such a structure as well, occurrence of cracks is suppressed since stress generated in the manufacturing process is alleviated in cavities 190.

### ASPECTS

(Clause 1) An electronic component according to one aspect includes: a multilayer body including a plurality of dielectric layers that are stacked; an external electrode disposed on at least one surface of external surfaces of the multilayer body; and internal electrodes disposed respectively in a plurality of layers of the multilayer body and connected to the external electrode. At least one cavity is formed in a dielectric layer between the internal electrodes, the at least one cavity being formed in a range of 0 μm to 200 μm in a first direction from a connecting position where the external electrode is connected to the internal electrodes, the internal electrodes extending in the first direction.
(Clause 2) In the electronic component according to Clause 1, the at least one cavity is formed in a range of 0 μm to 100 μm in the first direction, from the connecting position.
(Clause 3) In the electronic component according to Clause 1, the at least one cavity is formed in a range of 100 μm to 200 μm in the first direction from the connecting position.
(Clause 4) In the electronic component according to Clause 1, the at least one cavity includes a first cavity and a second cavity. The first cavity is formed in a range of 0 μm to 100 μm in the first direction from the connecting position. The second cavity is formed in a range of 100 μm to 200 μm in the first direction from the connecting position.
(Clause 5) In the electronic component according to Clause 1, the at least one cavity includes a third cavity and a fourth cavity. In a plan view in the first direction of the multilayer body, the third cavity is formed in a layer in which the fourth cavity is formed in the multilayer body, and the third cavity is formed at a position offset from the fourth cavity in a second direction orthogonal to the first direction.
(Clause 6) In the electronic component according to Clause 1, the at least one cavity is formed in 10% or more dielectric layers with respect to the dielectric layers disposed between the internal electrodes.
(Clause 7) In the electronic component according to Clause 6, the at least one cavity is formed in 50% or more dielectric layers with respect to the dielectric layers disposed between the internal electrodes.
(Clause 8) In the electronic component according to Clause 7, the at least one cavity is formed in all of the dielectric layers disposed between the internal electrodes.
(Clause 9) In the electronic component according to Clause 1, the internal electrodes are disposed on two or more dielectric layers of the multilayer body.
(Clause 10) In the electronic component according to Clause 9, the internal electrodes are disposed on 10 or more dielectric layers of the multilayer body.

It should be construed that the embodiments disclosed herein are given by way of illustration in all respects, not by way of limitation. It is intended that the scope of the present disclosure is defined by claims, not by the description above, and encompasses all modifications and variations equivalent in meaning and scope to the claims.

10 communication apparatus; 12 antenna; 20 radio frequency front-end circuit; 22, 28 bandpass filter; 24 amplifier; 26 attenuator; 30 mixer; 32 local oscillator; 40 D/A converter; 50 RF circuit; 100, 100X filtering device; 110 multilayer body; 111 upper surface; 112 lower surface; 113 to 116 lateral surface; 121, 122 shield conductor; 130, 135, PL1 plate electrode; 140 to 145 resonator; 150 to 155, 170 to 175 connecting conductor; 160 to 165, C10, C20, C30, C40, C50 capacitor electrode; 180 crack; 190, 230 cavity; 200 green sheet; 201 ceramic paste; 205, V10, V11 via; 206 region; 210 copper paste; 220 resin paste; T1 input terminal; T2 output terminal.

1. An electronic component comprising:
a multilayer body including a plurality of stacked dielectric layers;
an external electrode disposed on at least one surface of external surfaces of the multilayer body; and
internal electrodes disposed respectively in the plurality of stacked dielectric layers of the multilayer body and connected to the external electrode, wherein
at least one cavity is provided in a part of the dielectric layers between the internal electrodes, the at least one cavity being provided in a range of 10 μm to 200 μm in a first direction from a connecting position where the external electrode is connected to the internal electrodes, the internal electrodes extending in the first direction.

2. The electronic component according to claim 1, wherein the at least one cavity is provided in a range of 10 μm to 100 μm in the first direction from the connecting position.

3. The electronic component according to claim 1, wherein the at least one cavity is provided in a range of 100 μm to 200 μm in the first direction from the connecting position.

4. The electronic component according to claim 1, wherein
the at least one cavity includes a first cavity and a second cavity,
the first cavity is provided in a range of 10 μm to 100 μm in the first direction from the connecting position, and
the second cavity is provided in a range of 100 μm to 200 μm in the first direction from the connecting position.

5. The electronic component according to claim 1, wherein
the at least one cavity includes a third cavity and a fourth cavity, and
in a plan view in the first direction of the multilayer body, the third cavity is provided in a layer in which the fourth cavity is provided in the multilayer body, and the third cavity is provided at a position offset from the fourth cavity in a second direction orthogonal to the first direction.

6. The electronic component according to claim 1, wherein the at least one cavity is provided in 10% or more of the dielectric layers disposed between the internal electrodes.

7. The electronic component according to claim 6, wherein the at least one cavity is provided in 50% or more of the dielectric layers disposed between the internal electrodes.

8. The electronic component according to claim 7, wherein the at least one cavity is provided in all of the dielectric layers disposed between the internal electrodes.

9. The electronic component according to claim 1, wherein the internal electrodes are disposed on two or more of the dielectric layers of the multilayer body.

10. The electronic component according to claim 9, wherein the internal electrodes are disposed on 10 or more of the dielectric layers of the multilayer body.

11. A filtering device comprising:
a multilayer body including a plurality of stacked dielectric layers;
an external electrode disposed on at least one surface of external surfaces of the multilayer body; and
internal electrodes disposed respectively in the plurality of stacked dielectric layers of the multilayer body and connected to the external electrode, wherein at least one cavity is provided in a part of the dielectric layers between the internal electrodes, the at least one cavity being provided in a range of 10 μm to 200 μm in a first direction from a connecting position where the external electrode is connected to the internal electrodes, the internal electrodes extending in the first direction.

12. A dielectric filter comprising:
a multilayer body including a plurality of stacked dielectric layers and having a substantially cuboidal shape;
a plurality of resonators located inside the multilayer body and extending in a first direction orthogonal to a stacking direction of the multilayer body; and
a first shield conductor disposed on a first lateral surface of the multilayer body, the first lateral surface being orthogonal to the first direction, wherein
each resonator of the plurality of resonators includes a plurality of first conductors extending in the first direction, stacked together in the stacking direction, and each having a first end in the first direction, the first end being connected to the first shield conductor, and
in each resonator of the plurality of resonators, at least one cavity is provided in a part of the dielectric layers between the first conductors, the at least one cavity being provided in a range of 10 μm to 200 μm in the first direction from a connecting position where the shield conductor is connected to the first conductors.

13. The dielectric filter according to claim 12, further comprising:
a first plate electrode and a second plate electrode located inside the multilayer body and spaced from each other in the stacking direction; and
a second shield conductor disposed on a second lateral surface of the multilayer body opposite to the first lateral surface, wherein
the plurality of resonators is arranged between the first plate electrode and the second plate electrode,
the first shield conductor and the second shield conductor are connected to the first plate electrode and the second plate electrode, and
the plurality of resonators each have a second end in the first direction and the second end is spaced from the second shield conductor.

14. The dielectric filter according to claim 13, further comprising a capacitor electrode facing the second end of each resonator of the plurality of resonators, and connected to the second shield conductor, wherein
the capacitor electrode includes a plurality of second conductors extending in the first direction and stacked together in the stacking direction, and
in each resonator of the plurality of resonators, at least one cavity is provided in a part of the dielectric layers between the second conductors, the at least one cavity being provided in a range of 10 μm to 200 μm in the first direction from a connecting position where the second shield conductor is connected to the second conductors.
